(19) United States
(12) Patent Application Publication
(10) Pub. No.: US 2004/0174688 A1
(43) Pub. Date: Sep. 9, 2004

(54) PANEL STRUCTURE

(76) Inventors: Rong-Gui Lin, Taipei City (TW); Chien-Jen Hsieh, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/708,002

(22) Filed: Feb. 2, 2004

(30) Foreign Application Priority Data
Mar. 7, 2003 (TW) 092203499

(51) Int. Cl. H05K 7/14; H05K 7/18

(52) U.S. Cl. 361/801

(57) ABSTRACT

A panel structure installed on an electric device. The electric device includes a circuit board including at least one indicating lamp for displaying actions and at least one button switch for inputting the default command. The panel structure includes a panel connected to the electric device for covering the circuit board, the panel including at least one slotting, and at least one button installed between the circuit board and the panel for matching the slotting. The button includes a prominent part, a pressing part extended from the bottom of the prominent part, and an elastic frame extended from the bottom of the prominent part, wherein the one end of the elastic frame is connected to the panel for holding the button slightly protruded from the slotting when the button is not being forced and for making the pressing part contact with the button switch when the button is being forced.

### BACKGROUND OF INVENTION

1. Field of the Invention

The present invention relates to a panel structure, and more specifically, to a panel structure installed on an electric device for covering the electric device.

2. Description of the Prior Art

An optical disc drive is for reading data recorded on an optical disc and is a standard equipment of a personal computer. Please refer FIG. 1. FIG. 1 is a diagram of an optical disc drive of a computer. The optical disc drive includes a tray for carrying an optical disc. The optical disc drive further includes a circuit board in front of the optical disc drive. The circuit board includes an audio signal socket, sound volume tuner, tray switch, play/forward switch, and indicating lamps. The optical disc drive includes a panel in front of the optical disc drive for covering the front of the optical disc drive. There are some slots and buttons installed on the panel corresponding to the audio signal socket, sound volume tuner, tray switch, play/forward switch, and indicating lamps. So the outward appearance of the panel always lacks variation due to the location limitations mentioned above.

### SUMMARY OF INVENTION

It is therefore a primary objective of the present invention to provide a panel structure installed on an electric device for covering the electric device, to solve the problems mentioned above.

Briefly summarized, a panel structure installed on an electric device is proposed. The electric device includes a circuit board including at least one indicating lamp for displaying actions and at least one button switch for inputting the default command. The panel structure includes a panel connected to the electric device for covering the circuit board, the panel including at least one slotting, and at least one button installed between the circuit board and the panel for matching the slotting. The button includes a prominent part, a pressing part extended from the bottom of the prominent part, and an elastic frame extended from the bottom of the prominent part. One end of the elastic frame is connected to the panel for holding the button slightly protruded from the slotting when the button is not being forced and for making the pressing part contact with the button switch when the button is being forced.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of a conventional optical disc drive of a computer.

FIG. 2 is a diagram of a panel structure according to the present invention.

FIG. 3 and FIG. 4 are drawings of a combination of the panel and an optical disc drive according to the present invention.

FIG. 5 and FIG. 6 are sectional drawings of the panel structure according to the present invention.

FIG. 7 is a diagram of the buttons according to another embodiment of the present invention.

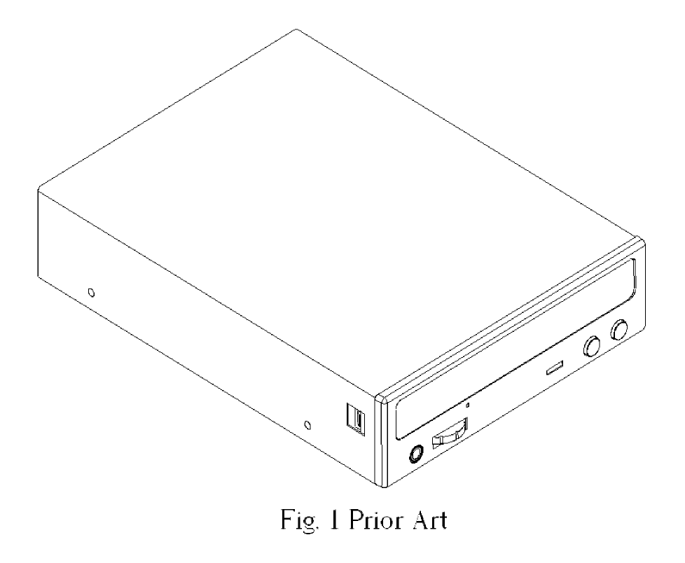

### DETAILED DESCRIPTION

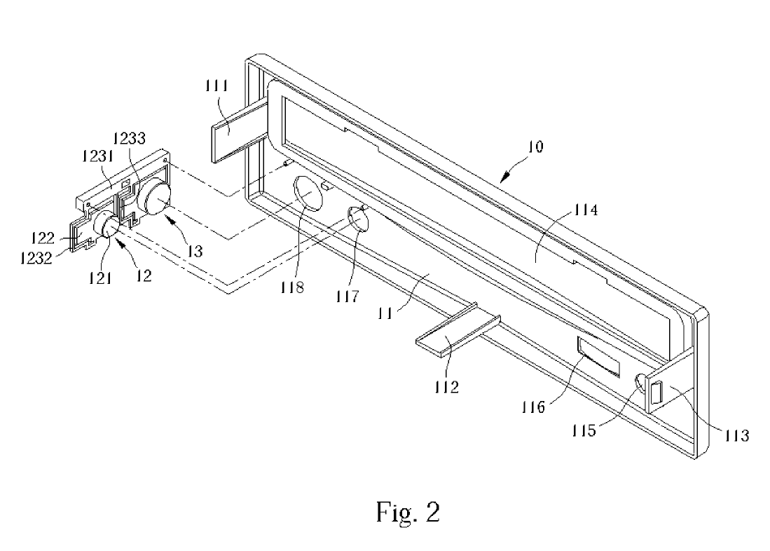

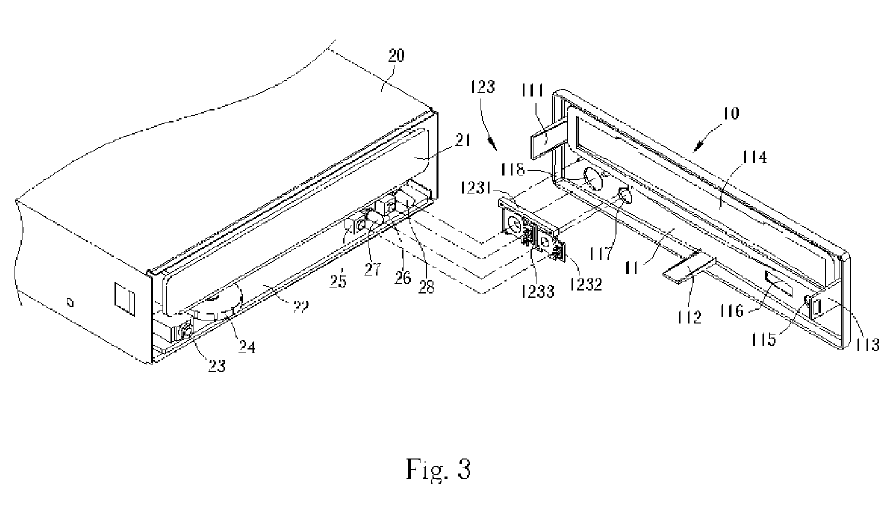

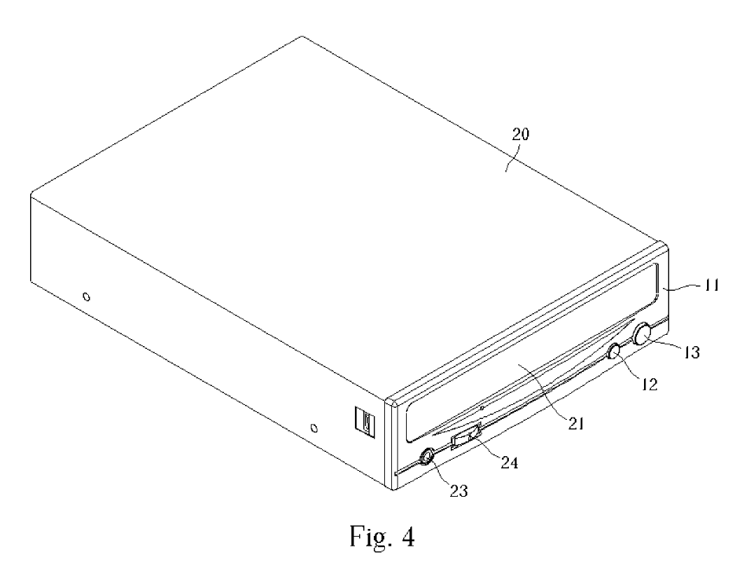

Please refer to FIG. 2, FIG. 3, and FIG. 4. FIG. 2 is a diagram of a panel structure 10 according to the present invention. FIG. 3 and FIG. 4 are drawings of a combination of the panel structure 10 and an optical disc drive 20 according to the present invention. The optical disc drive 20 includes a tray 21 for carrying an optical disc. The optical disc drive 20 further includes a circuit board 22 in front of the optical disc drive 20. The circuit board 22 includes an audio signal socket 23, a sound volume tuner 24, two button switches 25, 26 for inputting the default command of the optical disc drive 20, such as play, forward, stop, eject functions, and two indicating lamps 27, 28 for displaying actions of the optical disc drive 20. The panel structure 10 is for covering the front of the optical disc drive 20.

The panel structure 10 includes a panel 11 and two buttons 12, 13. The panel 11 is connected to the front of the optical disc drive 20 for covering the circuit board 22. The panel 11 includes three retainers 111, 112, 113 for combining the panel 11 with the optical disc drive 20. The panel 11 includes slots 114, 115, 116, 117, 118 corresponding to the tray 21, the audio signal socket 23, the sound volume tuner 24, and indicating lamps 27, 28. When the panel 11 is combined with the optical disc drive 20, the tray 21 can be ejected from the slot 114, and the audio signal socket 23 and the sound volume tuner 24 can protrude from the slots 115, 116 so that users can plug in a plug of an earphone into the audio signal socket 23 and turn the sound volume tuner 24.

The buttons 12, 13 are installed between the circuit board 22 and the panel 11 and are located in positions corresponding to the slots 117, 118. The structures of the button 12 and the button 13 are the same. The button 12 includes a prominent part 121 and a pressing part 122. The prominent part 121 is a hollow cylinder and is transparent. The one end of the prominent part is closed and the other end is open. The prominent part 121 is protruded from the slot 117 slightly so that users can press the prominent part 121. The pressing part 122 is extended from the bottom of the prominent part 121 and located in a position corresponding to the button switch 25 on the circuit board 22.

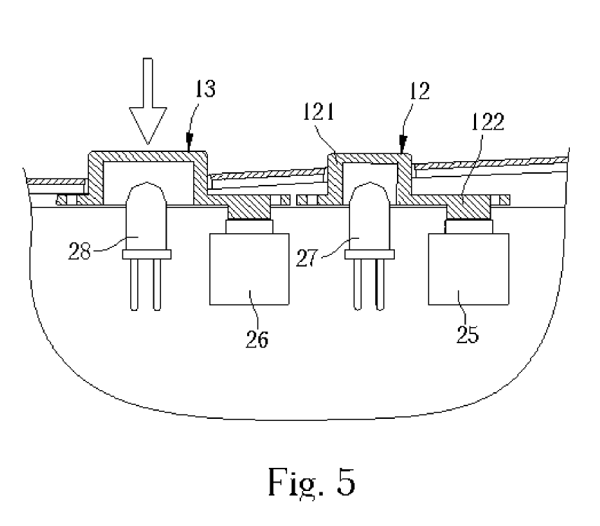

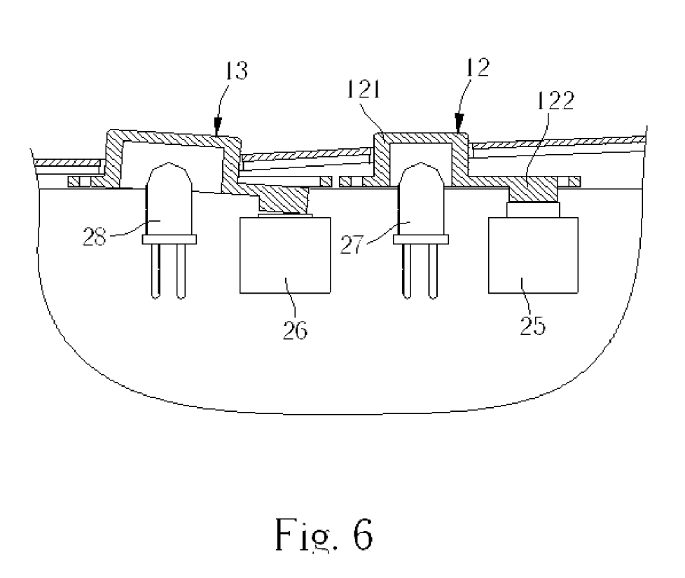

Furthermore, an elastic frame 123 is extended from the bottom of the prominent part 121. The elastic frame 123 includes a joint part 1231 and a couple of cantilevers 1232, 1233. The button 12 is connected to the panel 11 via the joint part 1231. The one end of the cantilevers 1232, 1233 is connected to the joint part 1231, and the other end is connected to the pressing part 122. The cantilevers 1232, 1233 can support the button 12 so that the button 12 can be held in a position such that the button 12 is slightly protruded from the slot 117 when the button 12 is not pressed by users. Please refer to FIG. 5 and FIG. 6. FIG. 5 and FIG. 6 are sectional drawings of the panel structure 10 according to the present invention. As shown in FIG. 6, when users press the closed end of the prominent part 121, the pressing part 122 can be moved to a certain displacement so that the pressing part 122 of the button 12 can press the button switch 25. When users remove the force from the closed end of the prominent part 121, the button 12 can be held in the original position by the restoring force provided by the cantilevers 1232, 1233.

The button 12 consists of the prominent part 121 and the pressing part 122. The pressing part 122 is next to the prominent part 121. The prominent part 121 is a hollow cylinder and located in a position corresponding to the indicating lamp 27. Because the prominent part 121 is made of transparent material so that the light emitted by the indicating lamp 27 can pass through the prominent part 121 directly, users can see the light from the indicating lamp. Therefore, the button 12 and the indicating lamp 27 can be integrated in the same position, and there is no need to arrange another place to locate the indicating lamp. So the structural design of the panel 11 can be simplified, and more outward appearance designs can be applied to the panel 11.

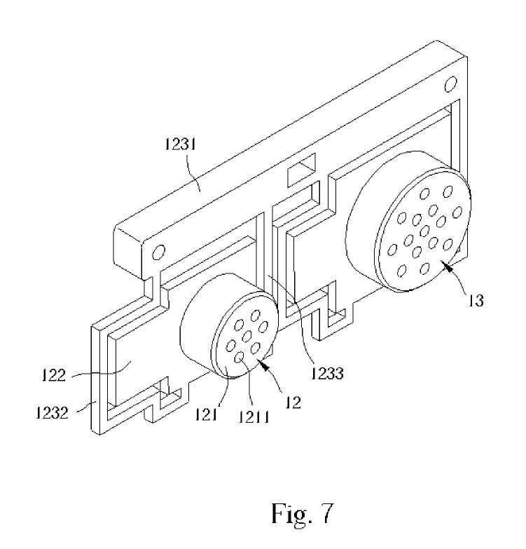

Please refer to FIG. 7. FIG. 7 is a diagram of the buttons 12, 13 according to another embodiment of the present invention. The prominent part 121 of the button 12 includes a plurality of holes 1211 on the closed end of the prominent part 121. Therefore, the prominent part 121 of the button 12 does not have to be made of transparent material, and the light emitted by the indicating lamp 27 can pass through holes 1211 directly. Users still can see the light from the indicating lamp 27.

Those skilled in the art will readily observe that numerous modifications and alterations of the device and the method may be made while retaining the teachings of the invention. Accordingly, the above disclosure should be construed as limited only by the metes and bounds of the appended claims.

1. A panel structure installed on an electric device, the electric device comprising a circuit board comprising at least one indicating lamp for displaying actions of the electric device and at least one button switch for inputting the default command of the electric device, the panel structure comprising:
a panel connected to the electric device for covering the circuit board, the panel comprising at least one slotting; and
at least one button installed between the circuit board and the panel for matching the slotting, comprising:
a prominent part, which is hollow and transparent and is protruded from the slotting;
a pressing part extended from the bottom of the prominent part; and
an elastic frame extended from the bottom of the prominent part, wherein the one end of the elastic frame is connected to the panel for holding the button slightly protruded from the slotting when the button is not being forced and for making the pressing part contact with the button switch when the button is being forced.

2. The panel structure of claim 1, wherein the panel further comprises a plurality of retainers for combining with the electric device.

3. The panel structure of claim 1, wherein the prominent part comprises a plurality of holes pervious to light emitted by the indicating lamp.

4. The panel structure of claim 1, wherein the elastic frame comprises a joint part connected to the panel and a cantilever connected to the joint part and the pressing part.
